(19) United States
(12) Patent Application Publication
(10) Pub. No.: US 2026/0358371 A1
(43) Pub. Date: Nov. 12, 2026

(54) PROBE AND ELECTRICAL CONNECTION APPARATUS

(71) Applicant: Kabushiki Kaisha Nihon Micronics, Tokyo (JP)

(72) Inventors: Yuto NARA, Aomori (JP); Naoki FUKUSHI, Aomori (JP); Takuya MATSUO, Aomori (JP); Masayuki TAKAHASHI, Aomori (JP); Toshinori OMORI, Aomori (JP)

(73) Assignee: Kabushiki Kaisha Nihon Micronics, Tokyo (JP)

(21) Appl. No.: 19/736,132

(22) Filed: Jul. 9, 2026

Related U.S. Application Data
(63) Continuation of application No. PCT/JP2025/002031, filed on Jan. 23, 2025.

(30) Foreign Application Priority Data
Jan. 30, 2024 (JP) 2024-011687

(51) Int. Cl. G01R 1/067; G01R 1/04

(52) U.S. Cl. CPC G01R 1/06722; G01R 1/0416; G01R 1/06738

(57) ABSTRACT

A probe has a tip end portion arranged at one end portion in the axial direction and brought into contact with the inspection object, a base end portion arranged at the other end portion, a plurality of coil spring portions having elasticity arranged between the tip end portion and the base end portion, and a connection portion having no elasticity. The probe has a rectangular shape having four side surfaces when viewed in the axial direction. The plurality of coil spring portions are connected along the axial direction via a connection portion.

### CROSS-REFERENCE TO RELATED APPLICATIONS

The present application is a continuation of International Application No. PCT/JP 2025/002031, filed on Jan. 23, 2025, and based upon and claims the benefit of priority from Japanese Patent Application No. 2024-011687, filed on Jan. 30, 2024, the entire contents of which are incorporated herein by reference.

### TECHNICAL FIELD

The present invention relates to a probe and an electrical connection apparatus used for inspecting the electrical characteristics of an inspection object.

### BACKGROUND ART

An electrical connection apparatus including a probe is used to inspect the electrical characteristics of an inspection object, such as a semiconductor integrated circuit, in a wafer state. In inspection using the probe, one end portion of the probe contacts an electrode of the inspection object, and the other end portion of the probe contacts a terminal (hereinafter also referred to as “land”) arranged on a substrate included in the electrical connection apparatus. The land is electrically connected to an inspection apparatus such as a tester.

In order to inspect the electrical characteristics of the inspection object accurately, it is necessary to connect the inspection object and the land via the probe stably electrically. Therefore, when the probe itself does not have elasticity in the axial direction, a method of holding the probe in a curved state in a probe head or the like of the electrical connection apparatus is adopted. The probe can be stably brought into contact with the inspection object and the land by the elasticity of the probe by overdrive in which the curved probe is pressed against the inspection object and the probe is further curved.

### SUMMARY

However, in the electrical connection apparatus which holds the probe in a curved state, when the probe needs to be replaced, it is necessary to remove the probe from the probe head after returning the probe held by the probe head from the curved state to the straight state. Therefore, there has been a problem that replacing the probe takes time.

In view of the above problems, an object of the present invention is to provide a probe and an electrical connection apparatus which facilitate the replacement of the probe in the electrical connection apparatus.

A probe according to one aspect of the present invention has a tip end portion arranged at one end portion in the axial direction and brought into contact with an inspection object, a base end portion arranged at the other end portion, a plurality of elastic coil spring portions arranged between the tip end portion and the base end portion, and a non-elastic connection portion. The probe has a rectangular shape having four side surfaces when viewed from the axial direction. The plurality of coil spring portions are connected along the axial direction via the connection portion.

According to the present invention, it is possible to provide a probe and an electrical connection apparatus which facilitate the replacement of the probe in the electrical connection apparatus.

### BRIEF DESCRIPTION OF THE DRAWINGS

FIG. 1 is a schematic side view illustrating a configuration of a probe according to an embodiment.

FIG. 2 is a schematic plan view illustrating the configuration of the probe according to the embodiment.

FIG. 3 is a schematic view illustrating a first component constituting the probe shown in FIG. 1.

FIG. 4 is a schematic view illustrating a second component constituting the probe shown in FIG. 1.

FIG. 5 is a schematic view illustrating a third component constituting the probe shown in FIG. 1.

FIG. 6 is a schematic view illustrating a configuration of a coil spring portion of the probe according to the embodiment.

FIG. 7 is a schematic perspective view illustrating the coil spring portion of the probe according to the embodiment.

FIG. 8 is a schematic view illustrating a connection between a tip end portion of the probe shown in FIG. 1 and a current path member.

FIG. 9 is a schematic view illustrating a connection between a connection portion of the probe shown in FIG. 1 and the current path member.

FIG. 10 is a schematic view illustrating the shape of each line of the coil spring portion of the probe according to the embodiment.

FIG. 11 is a schematic view illustrating a configuration of an electrical connection apparatus according to the embodiment.

FIG. 12 is a schematic view illustrating another configuration of an electrical connection apparatus according to the embodiment.

FIG. 13 is a schematic view illustrating a first component constituting a probe according to a first modification example of the embodiment.

FIG. 14 is a schematic view illustrating a second component constituting the probe according to the first modification example of the embodiment.

FIG. 15 is a schematic view illustrating a third component constituting the probe according to the first modification example of the embodiment.

FIG. 16 is a schematic view illustrating a current path member of the probe according to the first modification example of the embodiment.

FIG. 17 is a schematic side view illustrating a configuration of the probe according to the first modification example of the embodiment.

FIG. 18 is a schematic view illustrating a method of connecting a current path member of the probe shown in FIG. 17.

FIG. 19 is a schematic view illustrating a first component constituting a probe according to a second modification example of the embodiment.

FIG. 20 is a schematic view illustrating a second component constituting the probe according to the second modification example of the embodiment.

FIG. 21 is a schematic view illustrating a third component constituting the probe according to the second modification example of the embodiment.

FIG. 22 is a schematic side view illustrating a configuration of the probe according to the second modification example of the embodiment.

FIG. 23 is a schematic view illustrating a method of connecting a current path member of the probe shown in FIG. 22.

FIG. 24 is a schematic cross-sectional view illustrating an example of an opening shape of a connection portion of a probe according to another embodiment.

FIG. 25 is a schematic cross-sectional view illustrating another example of an opening shape of a connection portion of a probe according to another embodiment.

### DESCRIPTION OF EMBODIMENTS

Next, embodiments of the present invention will be described with reference to the drawings. In the following description of the drawings, identical or similar parts are denoted by identical or similar reference numerals. It should be noted, however, that the drawings are illustrated schematically, and the proportions of the thickness of each part is different from the actual proportions. In addition, it is needless to say that there are parts in which the relationship or proportion of the dimensions are different between the drawings. The following embodiments exemplify an apparatus and a method for embodying a technical idea of the present invention, and the embodiments of the present invention do not limit the material, shape, structure, arrangement, and the like of the components as follows.

### First Embodiment

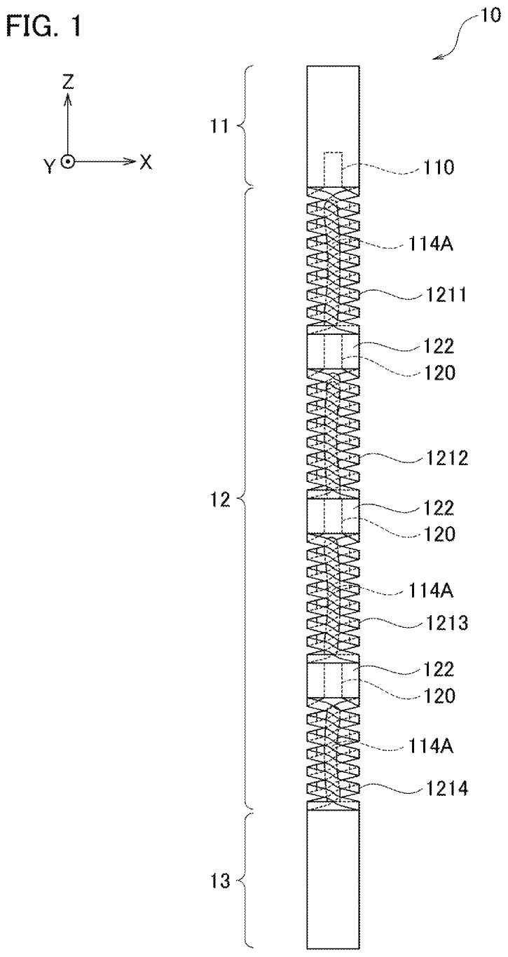

A probe 10 according to the first embodiment shown in FIG. 1 is used for inspecting the electrical characteristics of an inspection object. The probe 10 has a tip end portion 11 arranged at one end portion in the axial direction of the probe 10 and brought into contact with the inspection object, and a base end portion 13 arranged at the other end portion in the axial direction of the probe 10. The probe 10 further has a plurality of elastic coil spring portions and a connection portion 122 arranged between the tip end portion 11 and the base end portion 13. The plurality of coil spring portions are connected in the axial direction via the connection portion 122. In the probe 10, a part located between the tip end portion 11 and the base end portion 13 and including the coil spring portions and the connection portion 122 is defined as a body portion 12.

The probe 10 has a pillar shape having the tip end portion 11 and the base end portion 13 as both ends. As shown in FIG. 1, the axial direction of the probe 10 is defined as the Z direction, the left-right direction in FIG. 1 is defined as the X direction, and the depth direction in FIG. 1 is defined as the Y direction. Further, the direction in which the tip end portion 11 is positioned as seen from the base end portion 13 along the Z direction is defined as the upward direction, and the direction in which the base end portion 13 is positioned as seen from the tip end portion 11 is defined as the downward direction. Further, the upward facing surface of each portion of the probe 10 is defined as the upper surface, the downward facing surface is defined as the lower surface, and the surface connecting the upper and lower surfaces is defined as the side surface.

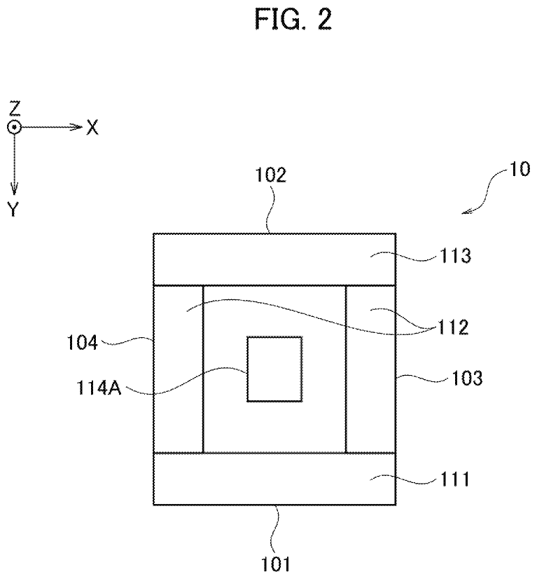

As shown in FIG. 2, the probe 10 has a rectangular shape having 4 side surfaces when viewed from the axial direction. A side surface viewed from the Y direction is designated as a first side surface 101, and a side surface facing opposite to the first side surface 101 is designated as a second side surface 102. A side surface viewed from the X direction is designated as a third side surface 103, and a side surface facing opposite to the third side surface 103 is designated as a fourth side surface 104. As will be described later, the coil spring portion of the probe 10 is constituted by combining a first component 111, a second component 112, and a third component 113. As shown in FIG. 2, the first side surface 101 is a surface of the first component 111, the second side surface 102 is a surface of the third component 113, and the third side surface 103 and the fourth side surface 104 are surfaces of the second component 112.

In the probe 10 shown in FIG. 1, the first coil spring portion 1211, the second coil spring portion 1212, the third coil spring portion 1213, and the fourth coil spring portion 1214 are sequentially connected from the tip end portion 11 toward the base end portion 13 via a connection portion 122. When each of the coil spring portions included in the probe 10 is not limited, it is referred to as “coil spring portion 121”. Although FIG. 1 exemplarily shows a case where the number of coil spring portions 121 included in the probe 10 is 4, the number of coil spring portions 121 included in the probe 10 can be arbitrarily set as long as it is 2 or more.

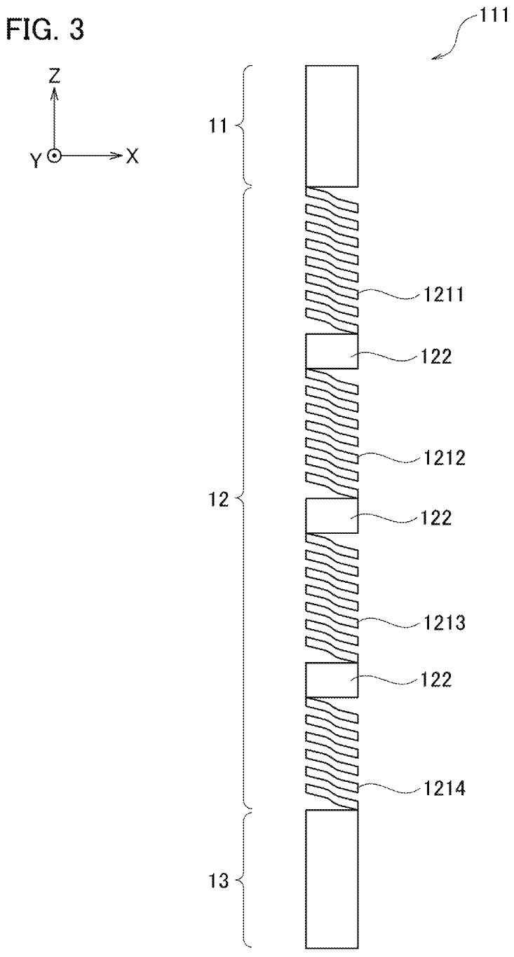

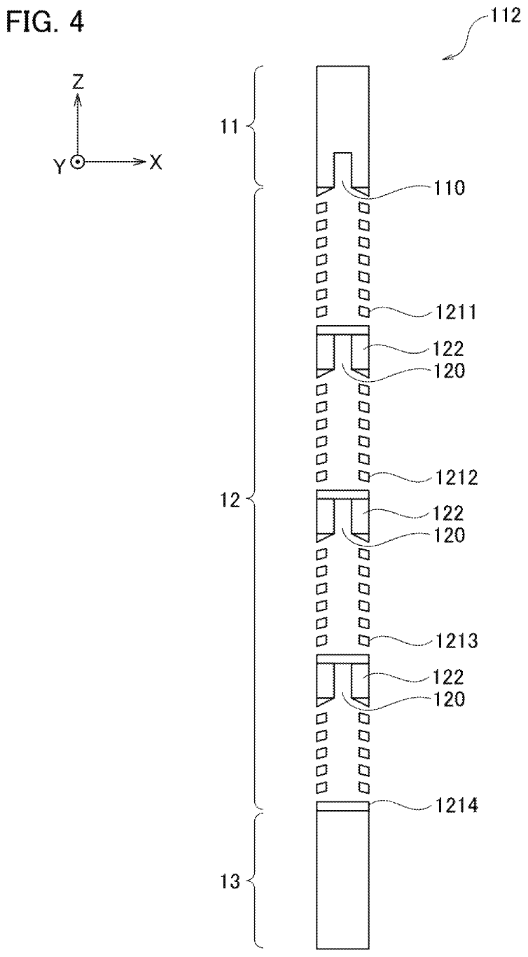

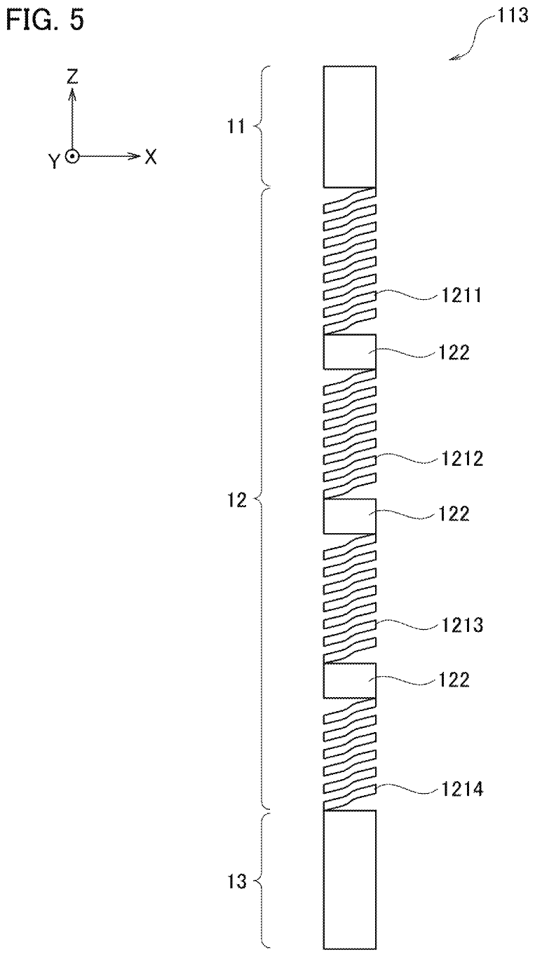

FIG. 3 shows a first component 111 constituting the probe 10. FIG. 4 shows a second component 112 constituting the probe 10. FIG. 5 shows a third component 113 constituting the probe 10. The first component 111 and the third component 113 have a structure in which beams (hereinafter also referred to as “diagonal beams”) extending obliquely to the X direction are arranged along the Z direction. The second component 112 has a structure in which beams (hereinafter also referred to as “parallel beams”) parallel to the Y direction are arranged along the Z direction.

The coil spring portion 121 of the probe 10 is constituted by stacking the third component 113, the second component 112, and the first component 111 in order along the Y direction. That is, the beam of the second component 112 connects the beam of the first component 111 and the beam of the third component 113 to constitute the coil spring portion 121.

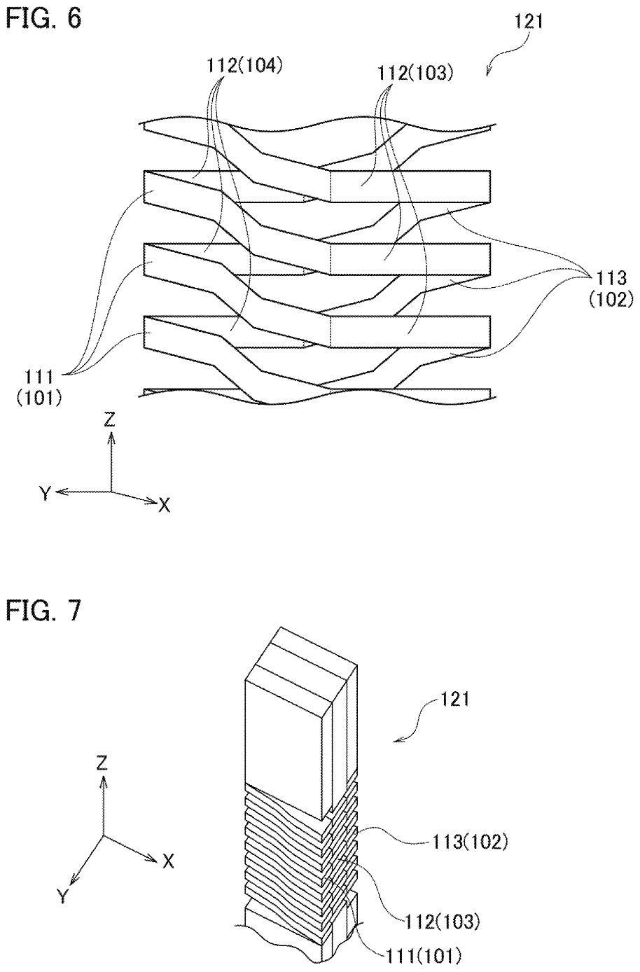

FIG. 6 shows a configuration of the coil spring portion 121. The first component 111 shown on the first side surface 101 includes an oblique beam extending from the upper left to the lower right in the drawing as seen from the normal direction of the first side surface 101. The third component 113 shown on the second side surface 102 includes an oblique beam extending from the upper right to the lower left in the drawing as seen from the normal direction of the first side surface 101. In other words, the oblique beam of the first component 111 and the oblique beam of the third component 113 are arranged symmetrically with respect to the central axis of the probe 10. As shown in FIG. 6, the coil spring portion 121 has a double helical structure. FIG. 7 is a perspective view of the coil spring portion 121.

Further, the probe 10 includes a current path member 114A arranged inside the coil spring portion 121. The current path member 114A is a columnar member having conductivity. The current path member 114A of the probe 10 shown in FIG. 1 bridges at least one of those between the tip end portion 11 and the connection portion 122, between the two connection portions 122, and between the base end portion 13 and the connection portion 122.

For example, the current path member 114A bridges the tip end portion 11 and the connection portion 122 connected to the other end of the coil spring portion 121 connected at one end to the tip end portion 11. Thus, the connection portion 122 closest to the tip end portion 11 and the tip end portion 11 are electrically connected.

Further, the current path member 114A bridges the base end portion 13 and the connection portion 122 connected to the other end of the coil spring portion 121 connected at one end to the base end portion 13. Thus, the connection portion 122 closest to the base end portion 13 and the base end portion 13 are electrically connected.

Further, the current path member 114A bridges two connection portions 122 connected to both ends of the coil spring portion. Thus, the two connection portions 122 are electrically connected.

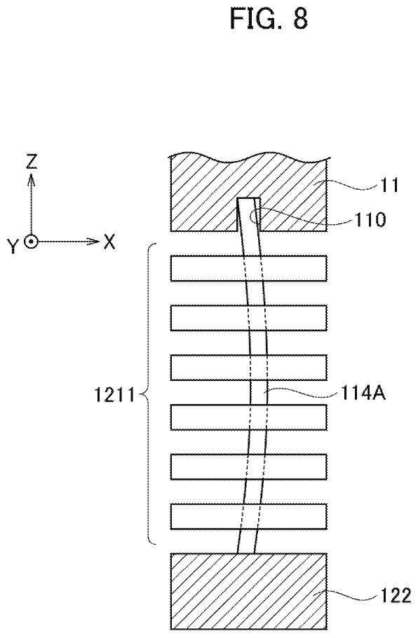

For example, as shown in FIG. 8, the current path member 114A disposed inside the first coil spring portion 1211 has its first end portion inserted into the first opening 110 formed on the lower surface of the tip end portion 11, and its second end portion connected to the upper surface of the connection portion 122. When the coil spring portion 121 expands and contracts, the first end portion of the current path member 114A slides inside the first opening 110.

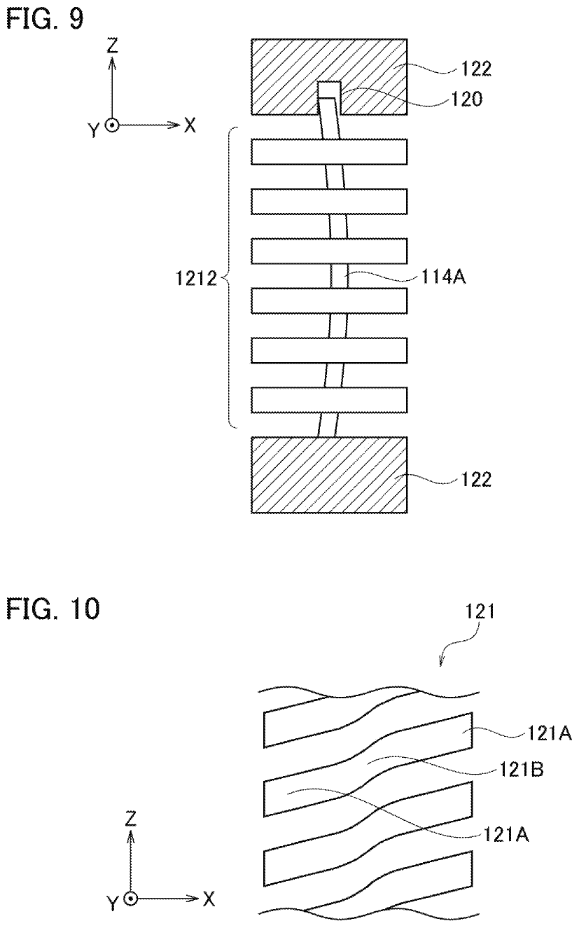

Further, as shown in FIG. 9, the current path member 114A disposed inside the second coil spring portion 1212 has its first end portion inserted into the second opening 120 formed on the lower surface of one connection portion 122, and its second end portion connected to the upper surface of the other connection portion 122. The current path member 114A disposed inside the third coil spring portion 1213 also electrically connects the two connection portions 122 in the same manner as the current path member 114A disposed inside the second coil spring portion 1212. The current path member 114A disposed inside the fourth coil spring portion 1214 has its first end portion inserted into the second opening 120 formed on the lower surface of the connection portion 122, and its second end portion connected to the upper surface of the base end portion 13. When the coil spring portion 121 expands and contracts, the first end portion of the current path member 114A slides inside the second opening 120.

As described above, when the coil spring portion 121 expands and contracts, the end portion of the current path member 114A slides inside the first opening 110 and the second opening 120. Therefore, even if the probe 10 expands and contracts in the axial direction, the current path member 114A is not bent and exposed to the outside of the coil spring portion 121.

The first component 111, the second component 112, the third component 113, and the current path member 114A are formed by processing a plate of a conductive material such as a metal material. Then, the third component 113, the second component 112, the current path member 114A, and the first component 111 are joined in this order to manufacture the probe 10. The beams of the first component 111 and the third component 113 function as springs, and the beams of the first component 111 and the third component 113 are connected to each other by the second component 112. In other words, the beams of the first component 111, the second component 112, and the third component 113 are connected to each other to constitute each line of the coil spring portion 121.

The probe 10 is stretchable in the axial direction by the coil spring portion 121 composed of the first component 111, the second component 112 and the third component 113. In other words, since the probe 10 itself has elasticity in the axial direction, it is not necessary to hold the probe 10 in a state of being curved at the probe head, for example.

Further, in the probe 10, the current path member 114A disposed inside the coil spring portion 121 functions as a current path between the tip end portion 11 and the base end portion 13. Therefore, even if the electrical resistance of the coil spring portion 121 is high due to a long path, the current path as the probe 10 can be shortened. In other words, the electrical resistance of the current path of the probe 10 can be reduced by the current path member 114A. In this way, the current path member 114A functions as a component for shortening the current path. It should be noted that the probe 10 does not need to include the current path member 114A if the electrical resistance of the coil spring portion 121 is at a level that does not affect the inspection of the inspection object.

As shown in FIG. 8, the current path member 114A may be arranged inside the coil spring portion 121 in a curved state. In this case, the curving directions of the plurality of current path members 114A arranged along the axial direction may be different, for example, the curving directions may be alternating along the axial direction.

The probe 10 may be made of, for example, nickel (Ni), a nickel alloy, gold (Au), silver (Ag), copper (Cu), palladium (Pd), a palladium alloy, rhodium (Rh), a rhodium alloy, or other noble metals. The current path member 114A may be made of a material having lower mechanical strength but having higher conductivity than the first component 111, the second component 112, and the third component 113. For example, a Ni alloy may be used for the first component 111 and the third component 113, and gold or copper may be used for the current path member 114A.

Each line of the coil spring portion 121 may not be linear when viewed from a direction perpendicular to the axial direction, but may include a curved portion. For example, as shown in FIG. 10, the traveling direction of each line may change in the middle of the side surface. Each line of the coil spring portion 121 shown in FIG. 10 includes a structure in which a first portion 121A extending at a first angle with respect to the axial direction and a second portion 121B extending at a second angle different from the first angle with respect to the axial direction are connected. In the example shown in FIG. 10, the second portion 121B is disposed between the first portion 121A and the first portion 121A. Since each line of the coil spring portion 121 includes a curved portion instead of a simple straight line, a load applied to the probe 10 is easily transmitted in the axial direction, and buckling of the probe 10 by bending from the central axis when a pushing force in the axial direction is applied to the probe 10 can be suppressed.

The elastic forces of the plurality of coil spring portions 121 included in the probe 10 need not be the same. For example, parts of the first coil spring portion 1211, the second coil spring portion 1212, the third coil spring portion 1213, and the fourth coil spring portion 1214 may have different numbers of turns of coils. Alternatively, all of the coil spring portions 121 may have different numbers of turns. As described above, one coil spring portion 121 of the two coil spring portions 121 having different elastic forces differs from the other coil spring portion 121 in the number of turns. The number of turns of coils of the coil spring portions 121 included in the probe 10 can be arbitrarily selected for each coil spring portion 121.

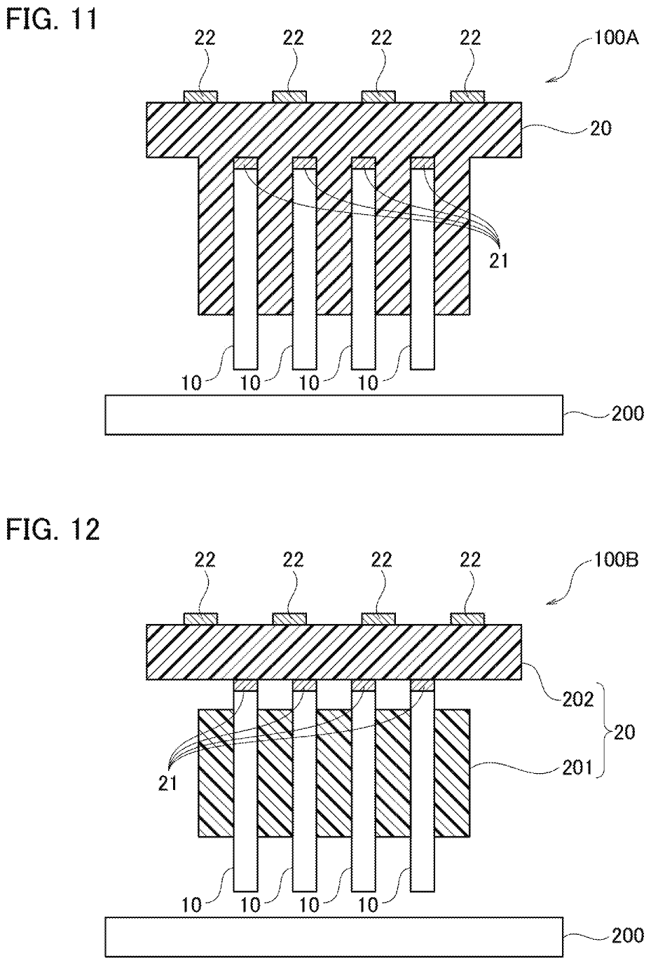

The probe 10 is used for the electrical connection apparatus 100A shown in FIG. 11, for example. The probe 10 is held by a holding portion 20 provided with an insertion hole into which the probe 10 is inserted. The probe 10 is inserted into the insertion hole of the holding portion 20 from the base end portion 13 side. A land 21 as a conductive terminal is disposed at the bottom of the insertion hole of the holding portion 20, and the end face of the base end portion 13 of the probe 10 is electrically connected to the land 21. The holding portion 20 includes an external terminal 22 electrically connected to the land 21 via an internal circuit (not shown). The external terminal 22 is electrically connected to an inspection apparatus such as an IC tester (not shown).

The base end portion 13 of the probe 10 may be joined to the land 21 to constitute the electrical connection apparatus 100A. A connection method and a connection material for joining the probe 10 to the land 21 may be arbitrarily selected. For example, the end face of the base end portion 13 of the probe 10 may be joined to the land 21 by soldering.

The holding portion 20 may be, for example, an integrally formed space transformer. Since the holding portion 20 is a space transformer, the arrangement interval of the external terminal 22 can be made larger than the arrangement interval of the probe 10. This facilitates connection between the electrical connection apparatus 100A and the inspection apparatus.

During inspection of the inspection object 200, the tip end portion 11 of the probe 10 comes into contact with an electrode pad (not shown) of the inspection object 200. Inspection of the inspection object 200 is performed by propagating an electrical signal between the inspection object and the inspection apparatus through the probe 10 and the holding portion 20.

Since the coil spring portion 121 of the probe 10 has elasticity, elastic deformation along the axial direction of the probe 10 is possible when the tip end portion 11 of the probe 10 in a state where the base end portion 13 is connected to the land 21 is brought into contact with the inspection object 200. Therefore, after bringing the probe 10 into contact with the inspection object 200, overdrive can be applied so as to press the probe 10 against the inspection object 200. By overdrive, electrical connection between the probe 10 and the inspection object 200 can be secured.

After the inspection of the inspection object 200 is completed, the probe 10 is separated from the inspection object 200. The probe 10 having the coil spring portion 121 returns to its original shape after being separated from the inspection object 200.

In FIG. 11, the probes 10 are shown to be held in line by the holding portion 20, but the arrangement of the probes 10 in the holding portion 20 is optional. For example, the probes 10 may be arranged in a matrix when viewed from the axial direction. Since the probes 10 are held linearly along the axial direction, the arrangement density of the probes 10 can be increased.

Further, the depth of the insertion hole of the holding portion 20 into which the probes 10 are inserted can be arbitrarily set. For example, by increasing the depth of the insertion hole, the probes 10 can be prevented from being held obliquely by the holding portion 20. Thus, it is possible to prevent the displacement of the tip end portion 11 at the inspection object with respect to the electrode pad of the inspection object 200.

As another example of the electrical connection apparatus including the probe 10, FIG. 12 shows an electrical connection apparatus 100B. The holding portion 20 of the electrical connection apparatus 100B includes a probe head 201 through which an insertion hole into which the probe 10 is inserted passes, and a wiring board 202 laminated on the probe head 201. A land 21 is arranged on the surface of the wiring board 202 facing the probe head 201. The wiring board 202 may be, for example, a space transformer.

As described above, the holding portion 20 for holding the probe 10 may be formed integrally as shown in FIG. 11, or may be formed by combining a plurality of components as shown in FIG. 12. For example, when the holding portion 20 is formed of a plurality of components, the manufacturing time of the holding portion 20 can be shortened by manufacturing the respective components in parallel.

The electrical connection apparatus may stack a printed circuit board having a wiring pattern electrically connected to the external terminal 22 on the holding portion 20. An electrical signal propagates between the inspection object and the inspection apparatus via the wiring pattern.

As described above, the probe 10 according to the embodiment is stretchable in the axial direction by having the coil spring portion 121. Therefore, it is not necessary to hold the probe 10 in a curved state in the electrical connection apparatus. Therefore, according to the probe 10 and the electrical connection apparatus including the probe 10, it is easy to replace the probe in the electrical connection apparatus.

### First Modification Example

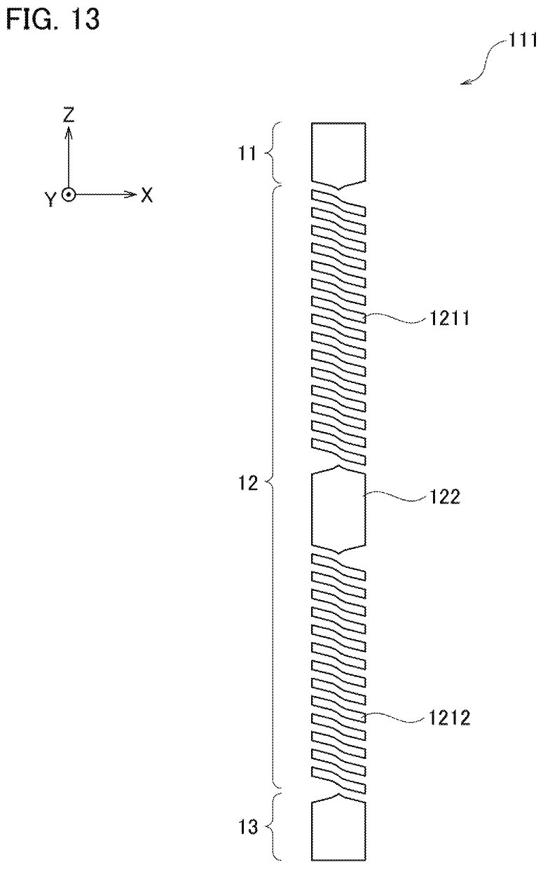

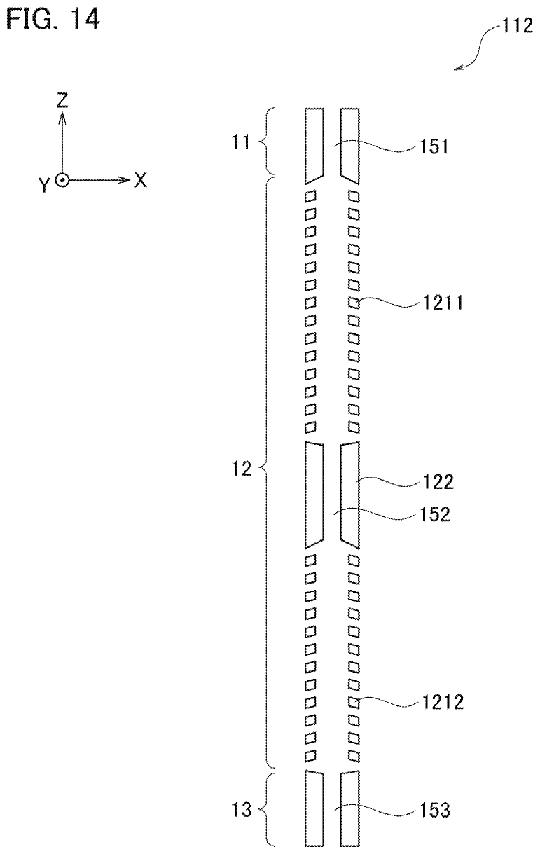

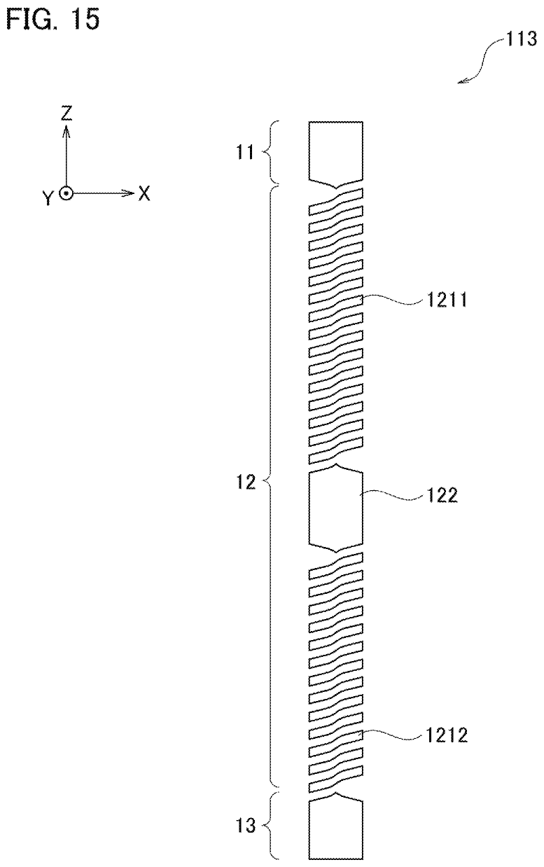

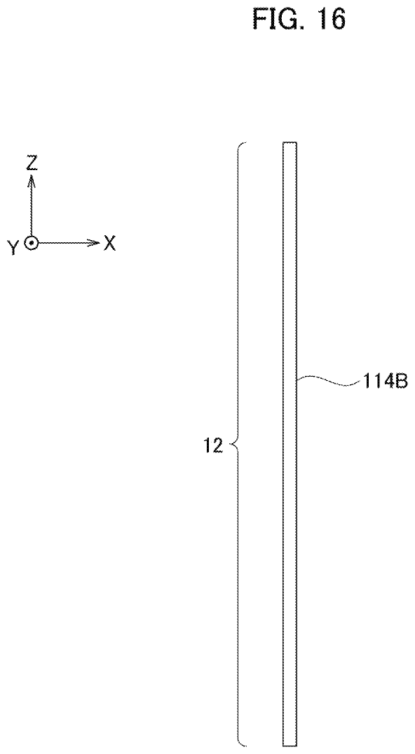

In the above description, the case where the current path members 114A are individually arranged in each of the coil spring portions 121 has been described. However, as shown in FIGS. 13 to 16, the probe 10 may be constructed by using the current path member 114B which is a single columnar member. FIG. 13 shows the structure of the first component 111. FIG. 14 shows the structure of the second component 112. FIG. 15 shows the structure of the third component 113. FIG. 16 shows the current path member 114B.

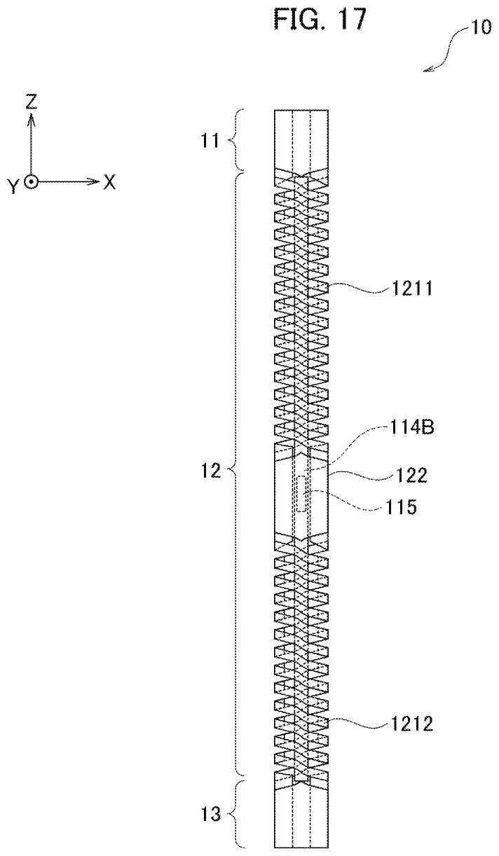

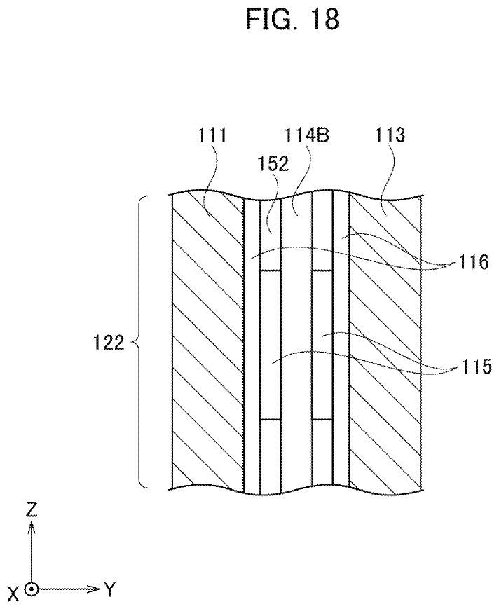

FIG. 17 shows a probe 10 in which a coil spring portion 121 is composed of the first component 111, the second component 112, and the third component 113 shown in FIGS. 13 to 15, respectively, and the current path member 114B shown in FIG. 16 is disposed inside the coil spring portion 121. The number of the coil spring portions 121 included in the probe 10 shown in FIG. 17 is 2.

In the probe 10 shown in FIG. 17, as shown in FIG. 14, a second through hole 152 penetrating in the axial direction is formed in the connection portion 122. The current path member 114B is disposed inside the coil spring portion 121 and the second through hole 152 of the connection portion 122, and bridges the tip end portion 11 and the base end portion 13. For example, the first end portion of the current path member 114B is inserted into the first through hole 151 formed in the tip end portion 11 shown in FIG. 14, and the second end portion is inserted into the third through hole 153 formed in the base end portion 13. When the coil spring portion 121 expands and contracts, the end portion of the current path member 114B slides inside the first through hole 151 and the third through hole 153.

The current path member 114B may be connected to the connection portion 122 of the first component 111 and the third component 113 by a connection component 115, for example, as shown in FIG. 18. The connection component 115 is disposed between the support plate 116 disposed inside the second through hole 152 and the current path member 114B, and joins the support plate 116 and the current path member 114B.

According to the probe 10 shown in FIG. 17, the electrical resistance of the current path can be reduced as compared with the probe 10 shown in FIG. 1 using a plurality of current path members 114A. Thus, the allowable value of the current flowing through the probe 10 can be increased.

### Second Modification Example

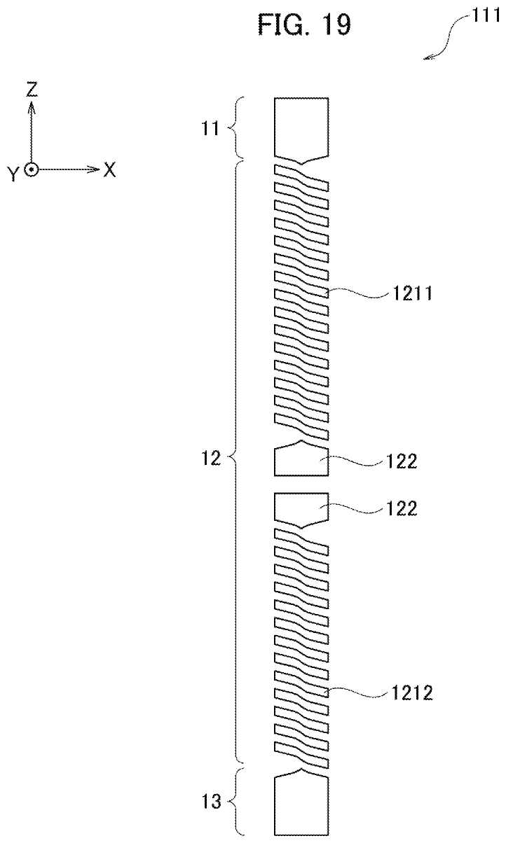

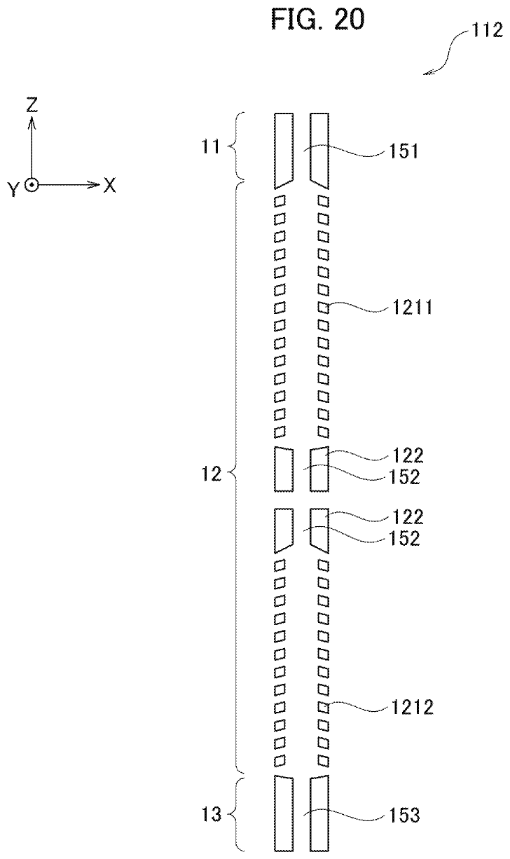

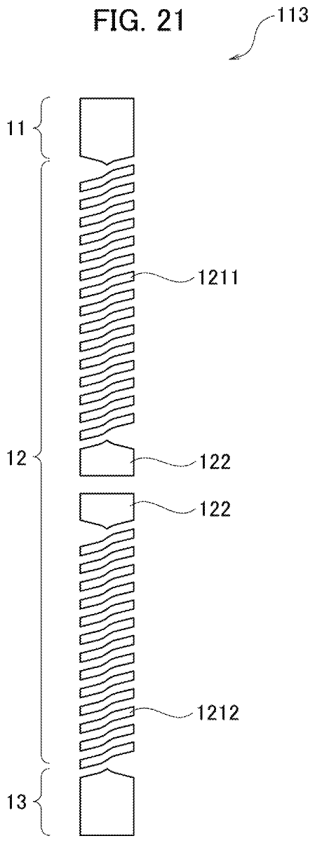

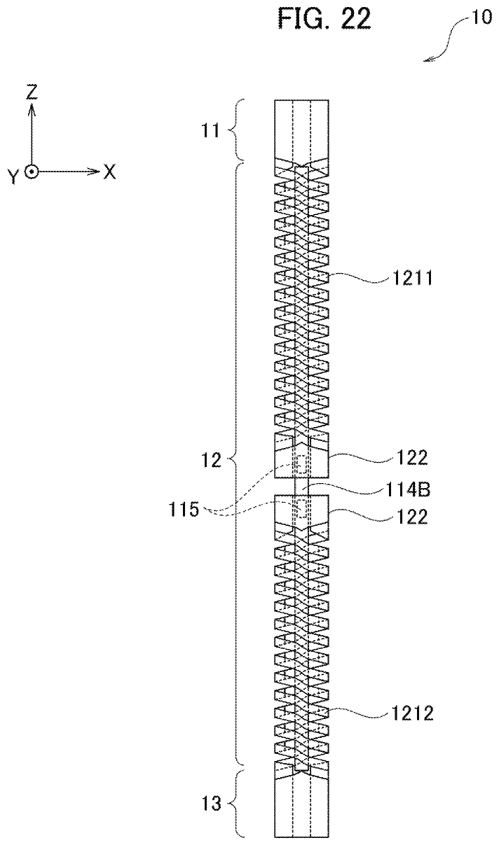

As the probe 10 using the current path member 114B which is a single columnar member, the coil spring portion 121 may be composed of a first component 111 shown in FIG. 19, a second component 112 shown in FIG. 20, and a third component 113 shown in FIG. 21. FIG. 22 shows a probe 10 in which the coil spring portion 121 is composed of the first component 111, the second component 112, and the third component 113 shown in FIGS. 19 to 21, respectively, and the current path member 114B shown in FIG. 16 is disposed inside the coil spring portion 121.

In the probe 10 shown in FIG. 22, the connection portion 122 connecting to the tip end portion 11 via the first coil spring portion 1211 and the connection portion 122 connecting to the base end portion 13 via the second coil spring portion 1212 are disposed so as to face and be spaced apart from each other in the axial direction. In other words, the body portion 12 is divided into 2 blocks.

In the probe 10 shown in FIG. 22, as in the probe 10 shown in FIG. 17, the current path member 114B is disposed inside the coil spring portion 121 and the second through hole 152 of the connection portion 122 to bridge the tip end portion 11 and the base end portion 13. The first end portion of the current path member 114B is inserted into the first through hole 151 formed in the tip end portion 11, and the second end portion is inserted into the third through hole 153 formed in the base end portion 13.

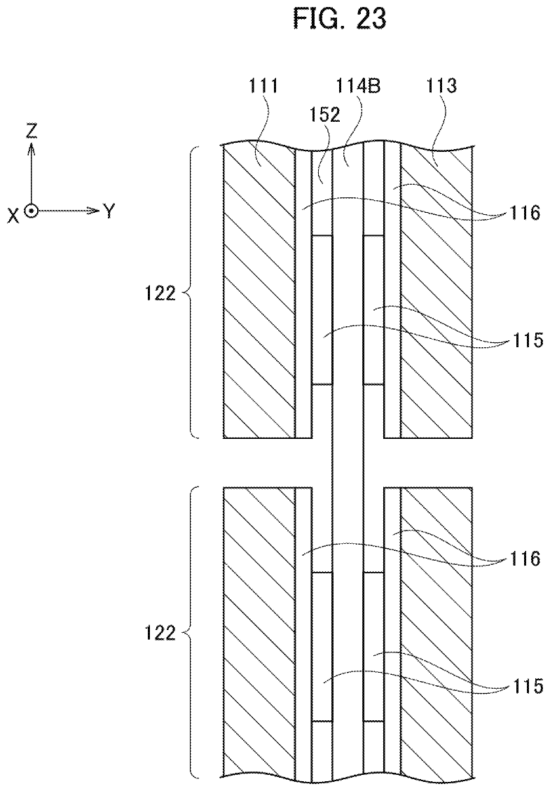

The current path member 114B may be connected to the connection portion 122 of the first component 111 and the third component 113 by connection components 115. For example, as shown in FIG. 23, the connection components 115 are disposed between a support plate 116 disposed inside the second through hole 152 of the connection portion 122 and the current path member 114B, and join the support plate 116 and the current path member 114B.

Although FIG. 22 shows a probe 10 including 2 coil spring portions 121, the number of coil spring portions 121 of the probe 10 is not limited to 2. One of the connection portions 122 electrically connecting via at least 1 coil spring portion 121 to the tip end portion 11 and another one of the connection portions 122 electrically connecting via at least 1 coil spring portion 121 to the base end portion 13 may be disposed apart along the axial direction. In other words, the body portion 12 may be divided into 2 or more arbitrary blocks.

### Other Embodiments

Although the invention has been described in terms of embodiments as described above, the description and drawings which form part of this disclosure should not be understood as limiting the invention. Various alternative embodiments, examples, and techniques of operation will become apparent to those skilled in the art from this disclosure.

For example, in the above example, the first opening 110, the second opening 120, the first through hole 151, the second through hole 152, and the third through hole 153 are opened perpendicularly to the upper surface or the lower surface of the tip end portion 11, the base end portion 13, or the connection portion 122. However, the opening shape of these openings and the through holes may have a tapered shape in which the area of the opening gradually decreases from the outside toward the center.

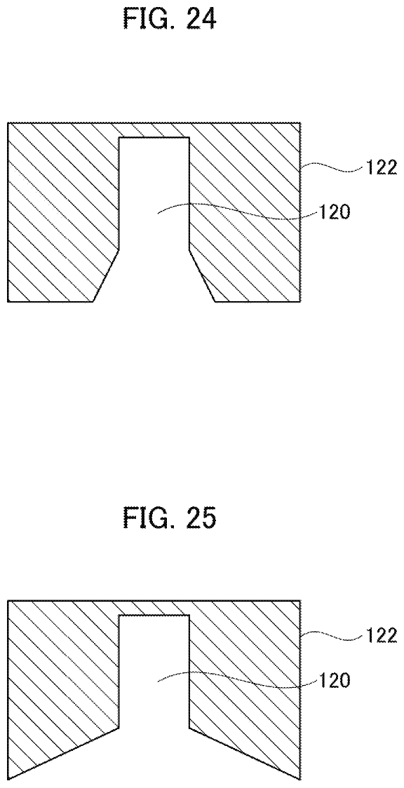

FIGS. 24 and 25 show examples in which the opening shape of the second opening 120 in the cross section along the axial direction is a tapered shape. With the tapered opening shape, the end portion of the current path member 114A is easily inserted into the first opening 110 and the second opening 120, and the end portion of the current path member 114B is easily inserted into the first through hole 151 and the third through hole 153.

Further, the electrical connection apparatus may be configured so that the base end portion 13 of the probe 10 and the land 21 can be freely contacted and separated. For example, the probe 10 may be held by the probe head 201 as in the electrical connection apparatus 100B shown in FIG. 12. Since the base end portion 13 is not joined to the land 21, the probe 10 can be easily replaced, for example, when a failure occurs in the probe 10.

As described above, the present invention includes various embodiments not described above.

1. A probe used for inspecting electrical characteristics of an inspection object, comprising:
a tip end portion disposed at one end in the axial direction and brought into contact with the inspection object;
a base end portion disposed at the other end;
a plurality of coil spring portions having elasticity disposed between the tip end portion and the base end portion; and
a connection portion having no elasticity; wherein
the probe has a rectangular shape having four side surfaces as viewed from the axial direction; and
the plurality of coil spring portions are connected along the axial direction via the connection portion.

2. The probe according to claim 1, wherein
the probe includes at least two of the coil spring portions each of which has elastic force different from each other.

3. The probe according to claim 2, wherein
one of the two coil spring portions each of which has elastic forces different from each other has a different number of turns than the other of the two coil spring portions.

4. The probe according to claim 1, wherein
each line of the coil spring portion includes a curved portion as viewed from a direction perpendicular to the axial direction.

5. The probe according to claim 1, further comprising
a conductive columnar member disposed inside the coil spring portion, wherein
the columnar member bridges at least one of those between the tip end portion and the connection portion, between the two connection portions, and between the base end portion and the connection portion.

6. The probe according to claim 1, further comprising
a single columnar member disposed inside the coil spring portion and the connection portion and bridging the tip end portion and the base end portion.

7. The probe according to claim 6, further comprising
a connection component for connecting the columnar member and the connection portion.

8. The probe according to claim 6, wherein
one of the connection portions electrically connecting to the tip end portion via at least one of the coil spring portions and another one of the connection portions electrically connecting to the base end portion via at least one of the coil spring portions are arranged to face and be spaced apart along the axial direction.

9. An electrical connection apparatus comprising:
the probe according to claim 1; and
a holding portion in which an insertion hole through which the probe is inserted from the base end portion is arranged, a terminal electrically connected to an end surface of the base end portion is arranged at a bottom of the insertion hole, and which holds the probe.

10. The electrical connection apparatus according to claim 9, wherein
the holding portion is a space transformer.

11. The electrical connection apparatus according to claim 9, wherein
the holding portion comprises:
a probe head through which the insertion hole passes; and
a wiring board laminated to the probe head and having the terminals arranged on a surface facing the probe head.
